(19) United States
(12) Patent Application Publication
(10) Pub. No.: US 2015/0262986 A1
(43) Pub. Date: Sep. 17, 2015

(54) OPTICAL COUPLING DEVICE

(71) Applicant: KABUSHIKI KAISHA TOSHIBA, Tokyo (JP)

(72) Inventors: Naoya TAKAI, Yukuhashi Fukuoka (JP); Yoshio NOGUCHI, Komatsu Ishikawa (JP); Mami YAMAMOTO, Nakatsu Oita (JP)

(21) Appl. No.: 14/474,298

(22) Filed: Sep. 1, 2014

(30) Foreign Application Priority Data
Mar. 14, 2014 (JP) 2014-052662

(51) Int. Cl. H01L 25/16; H01L 31/02; H01L 31/0216; H01L 31/167

(52) U.S. Cl. CPC H01L 25/167; H01L 31/167; H01L 25/165; H01L 25/162; H01L 31/02002; H01L 31/02164

(57) ABSTRACT

An optical coupling device includes a mounting member, a light receiving element, a first resin layer, a light emitting element, and a second resin layer. The mounting member includes an insulating layer having a recess in an upper surface thereof, input terminals, and output terminals insulated from the input terminals. The light receiving element is provided on a bottom surface of the recess. The first resin layer is provided in the recess and covers the light receiving element. The light emitting element is adhered to an upper surface of the first resin layer such that a lower surface of the light emitting element has a light emitting surface facing the light receiving surface, and is connected to the input terminals. The second resin layer covers the light emitting element, an upper surface of the insulating layer, the first resin layer, and the input terminals.

### CROSS-REFERENCE TO RELATED APPLICATION

This application is based upon and claims the benefit of priority from Japanese Patent Application No. 2014-052662, filed Mar. 14, 2014, the entire contents of which are incorporated herein by reference.

### FIELD

Embodiments described herein relate generally to an optical coupling device.

### BACKGROUND

An optical coupling device (such as a photocoupler or a photo-relay) may use a light emitting element to convert an input electric signal into a light signal, and use a light receiving element to receive the light, and output an electric signal. Therefore, the optical coupling device may transmit an electric signal in a state where input and output are insulated from each other.

In industrial apparatuses, office appliances, and household electrical appliances, different power supply systems such as a DC voltage system, an AC power supply system, a phone line system, and a control system are disposed inside one apparatus. However, if different power supply systems or circuit systems are directly joined, a malfunction may occur.

In this case, if an optical coupling device is used, since different power sources are insulated from each other, it is possible to maintain a normal operation.

For example, in an inverter air conditioner or the like, a number of photocouplers including a photocoupler for an AC load are used. Also, in order to perform signal switching for a semiconductor tester, a great number of photocouplers need to be mounted. However, it may be desirable to reduce the mounting area on a mounting member and reduce the sizes of photocouplers.

### DESCRIPTION OF THE DRAWINGS

FIG. 1A is a plan view schematically illustrating an optical coupling device according to a first embodiment.

FIG. 1B is a view schematically illustrating a cross section of the optical coupling device taken along a line A-A of FIG. 1A.

FIG. 1C is a side view schematically illustrating the optical coupling device.

FIG. 2A is a plan view schematically illustrating a state where a light receiving element has been mounted on a mounting member.

FIG. 2B is a schematic cross-sectional view taken along a line B-B of FIG. 2A.

FIG. 3A is a perspective view schematically illustrating a state where a first resin layer has been formed in a recess.

FIG. 3B is a schematic cross-sectional view taken along a line C-C of FIG. 3A.

FIG. 3C is a cross-sectional view schematically illustrating a state where the upper surface of the first resin layer has been planarized.

FIG. 4 is a cross-sectional view schematically illustrating a face-to-face type optical coupling device according to a comparative example.

FIG. 5A is a plan view schematically illustrating an optical coupling device according to a second embodiment.

FIG. 5B is a side view illustrating the optical coupling device.

FIG. 6A is a plan view schematically illustrating an optical coupling device according to a third embodiment.

FIG. 6B is a schematic cross-sectional view taken along a line E-E of FIG. 6A.

### DETAILED DESCRIPTION

Embodiments provide a small-sized optical coupling device capable of being mounted in a smaller area as compared to conventional optical coupling devices.

In general, according to one embodiment, an optical coupling device includes a mounting member, a light receiving element, a first resin layer, a light emitting element, and a second resin layer. The mounting member includes an insulating layer having a recess in an upper surface thereof, input terminals, and output terminals insulated from the input terminals. The light receiving element is provided on a bottom surface of the recess. The first resin layer is provided in the recess and covers the light receiving element. The light emitting element is adhered to an upper surface of the first resin layer such that a lower surface of the light emitting element has alight emitting surface facing the light receiving surface, and is connected to the input terminals. The second resin layer covers the light emitting element, an upper surface of the insulating layer, the first resin layer, and the input terminals.

Hereinafter, embodiments of the present disclosure will be described with reference to the accompanying drawings.

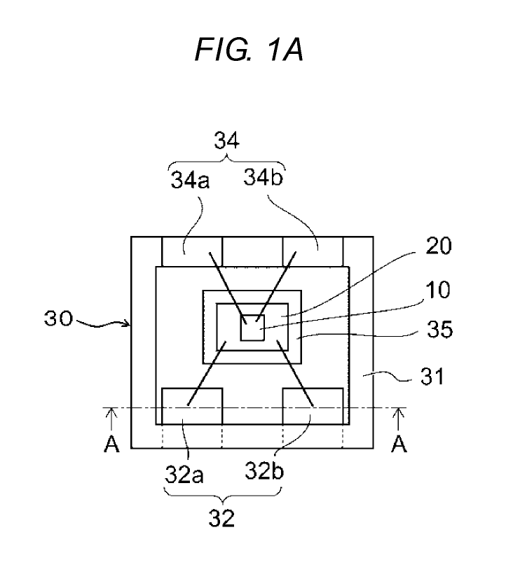

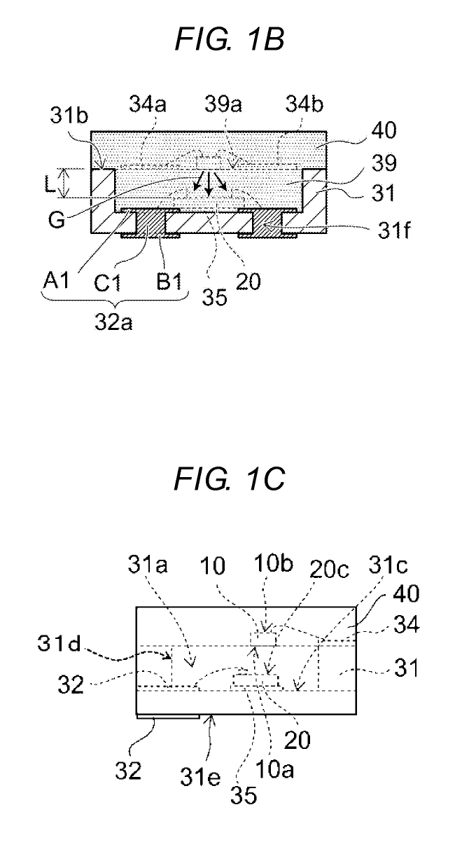

FIG. 1A is a plan view schematically illustrating an optical coupling device according to a first embodiment, FIG. 1B is a view schematically illustrating a cross section of the optical coupling device taken along a line A-A of FIG. 1A, and FIG. 1C is a side view schematically illustrating the optical coupling device.

The optical coupling device of the first embodiment includes a mounting member 30 having a recess 31a, a light emitting element 10, a light receiving element 20, a first resin layer 39, and a second resin layer 40. In FIG. 1A, the second resin layer 40 is not illustrated.

The mounting member 30 includes an insulating layer 31 having a light shielding property, input terminals 34, and output terminals 32. In FIGS. 1A to 1C, the mounting member 30 may include a molded interconnect device (MID), a multilayer ceramic, or the like.

In a case of an MID, the insulating layer 31 may be composed of an injection molded body of a resin such as a thermoplastic resin, or a ceramic. Also, the conductive layer of the input terminals 34, the output terminals 32, or the like may be formed by providing copper foil on or in the insulating layer 31, and patterning the copper foil.

In a case of a multilayer ceramic forming the insulating layer 31, a wiring layer including the input terminals 34 or the output terminals 32 may be a conductive layer of a thick film, a gold-plated layer provided on the conductive layer, and the like. Further, it is possible to form through-holes 31f in the ceramic (FIG. 1B), and connect the upper and lower sides of the multilayer ceramic by conductive layers. The ceramic may be formed of alumina, aluminum nitride, or the like.

The insulating layer 31 is provided with the recess 31a. The recess 31a is hollowed from the upper surface 31b of the insulating layer 31 and has a bottom surface 31c and an inner side surface 31d.

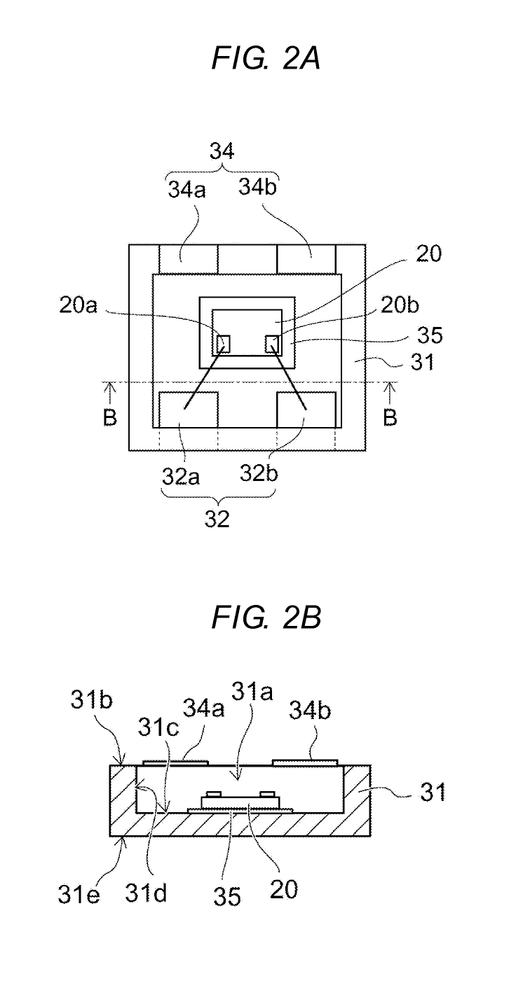

FIG. 2A is a plan view schematically illustrating a state where the light receiving element has been mounted on the mounting member, and FIG. 2B is a schematic cross-sectional view taken along a line B-B of FIG. 2A.

The light receiving element 20 is adhered to the bottom surface 31c of the recess 31a. In a case where a conductive layer 35 is provided on the bottom 31c, it is possible to adhere the light receiving element 20 by a solder material or the like. Alternatively, the light receiving element 20 may be adhered to the bottom 31c by an adhesive or the like. Electrodes 20a, 20b of the light receiving element 20 are connected to the output terminals 32.

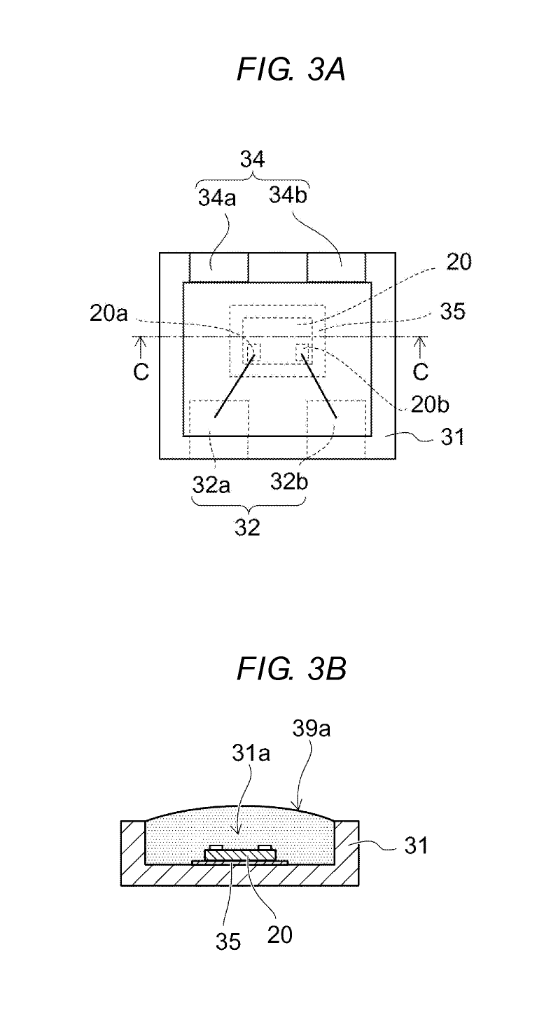

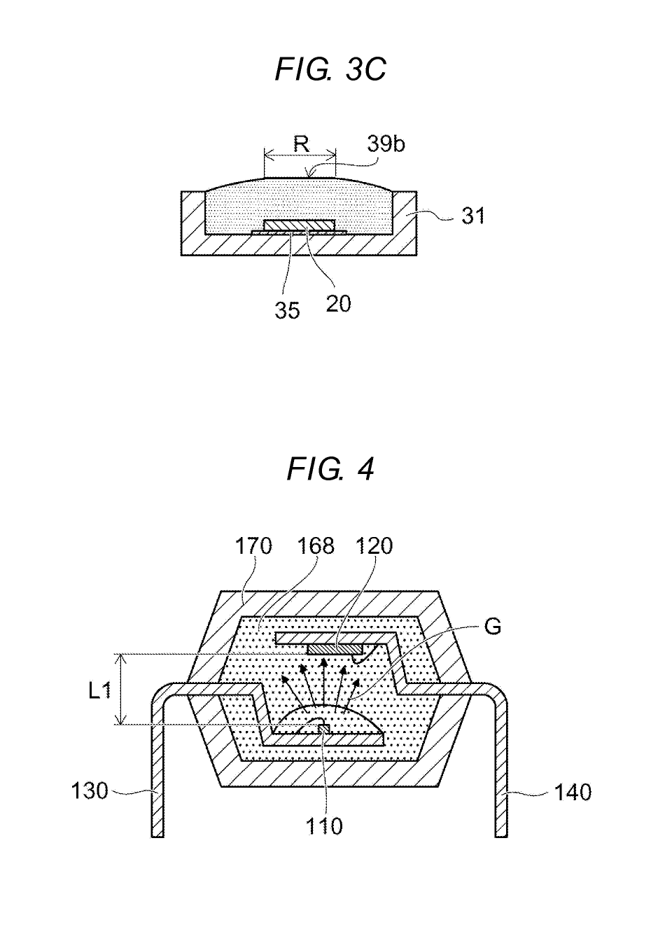

In a case where the light receiving element 20 is a photodiode, its electrodes 20a and 20b such as an anode and a cathode are connected to the output terminals 32a and 32b by bonding wires. Further, if a resin solution having a light transmitting property is filled into the recess 31a, and when the resin solution is cured, it is possible to form the first resin layer 39 (FIG. 3B). On the upper surface 31b of the insulating layer 31, it is possible to provide the input terminals 34.

Also, as illustrated in FIG. 1B, in the insulating layer 31, holes 31f may be formed to connect the bottom inner surface 31c and the lower outer surface 31e of the insulating layer 31. In this case, the output terminals 32 may be connected to conductive regions A1 provided at the bottom inner surface 31c, and conductive regions B1 provided at the lower outer surface 31e, through conductive portions C1 formed in the holes 31f.

The light emitting element 10 is adhered to the upper surface 39a of the cured first resin layer 39 by an adhesive or the like. In a case where the light emitting element 10 is a light emitting diode (LED), the anode and the cathode are connected to the input terminals 34a and 34b by bonding wires or the like. FIG. 1A is a plan view schematically illustrating that state (before the second resin layer 40 is provided).

FIG. 1B is a cross-sectional view schematically illustrating the optical coupling device having the second resin layer 40 provided so as to cover the light emitting element 10. If dies are used, it is possible to accurately form the second resin layer 40. The first resin layer 39 and the second resin layer 40 may be formed of a thermoset resin such as a silicon resin or an epoxy resin. Also, if the second resin layer 40 has a light shielding property, it is possible to suppress malfunctions of the detector of the apparatus attributable to ambient light.

The light emitting element 10 includes a light emitting layer which is formed of AlGaAs, InAlGaAs, InAlGaP, or the like, and emits light having a wavelength of 800 nm to 1000 nm. The lower surface 10a of the light emitting element 10, and the upper surface (light receiving surface) 20c of the light receiving element 20 are disposed so as to face each other with the first resin layer interposed therebetween. The emitted light G (FIG. 1B) efficiently enters the light receiving element 20. If the light receiving element 20 is a Si photodiode, it is possible to improve light sensitivity at and between 800 nm to 1000 nm wavelengths of light.

According to this structure, a dielectric strength voltage between the input terminals 34 and the output terminals 32 varies according to a distance L between the lower surface 10a of the light emitting element 10 and the upper surface 20c of the light receiving element 20. The distance L may be determined so as to satisfy a required dielectric strength voltage and an insulator thickness (determined according to safety standards). In a case where the first resin layer 39 is formed of silicon, it is possible to set the distance L to 0.4 mm or the like.

FIG. 3A is a perspective view schematically illustrating a state where the first resin layer has been formed in the recess, FIG. 3B is a schematic cross-sectional view taken along a line C-C of FIG. 3A, and FIG. 3C is a cross-sectional view schematically illustrating a state where the upper surface of the first resin layer has been planarized.

It often occurs that the central portion of the surface 39a of the first resin layer 39 formed of silicone or the like is not planer, having a central swollen portion as shown in FIG. 3B. The size of the light emitting element 10 is, for example, 400 μm by 400 μm.

If the resin is cured in a state where the light emitting element 10 is inclined, the emission direction of the light is variable from device to device. For this reason, for example, in a process such as automatic wire bonding, the accuracy of recognition of a pattern of the front surface of the light emitting element 10 may lowered to a point where it may be impossible to accurately perform bonding. Also, the tip portion of a capillary may come into contact with an electrode of the light emitting element 10 which is inclined, resulting in insufficient bond strength.

If a surface 39b of a region R to which the light emitting element 10 will be adhered is planarized as in FIG. 3C by polishing or the like, it is possible to mount the light emitting element 10 such that the upper surface 10b of the light emitting element 10 is substantially parallel to the bottom inner surface 31c of the recess 31a. Therefore, it is possible to accurately control the bonding position, and to improve the bonding strength, of the light emitting element 10 to the resin.

FIG. 4 is a cross-sectional view schematically illustrating a face-to-face type optical coupling device according to a comparative example.

In the comparative example, a light emitting element 110 adhered to an input lead 130, and a light receiving element 120 adhered to an output lead 140 are provided so as to face each other inside a translucent resin layer 168. However, an input lead frame, and an output lead frame are separate lead frames. Therefore, it may be necessary to bond the input lead frame and the output lead frame while simultaneously accurately maintaining a distance L1 between the light emitting surface of the light emitting element and the light receiving surface of the light receiving element. Also, it may not be easy to prevent a change (variation) of the distance L1 from device to device. Further, since outer leads protrude from a molded resin body, it may be difficult to reduce the size of the device.

In contrast to this, according to the first embodiment, the mounting and wire bonding processes of the first embodiment is more suitable to mass production. Therefore, it may be possible to reduce the cost of production. Also, the input terminals 34 and the output terminals 32 do not protrude laterally from the mounting member. Therefore, the size of the optical coupling device may be reduced, and the optical coupling device may be suitable for surface mounting.

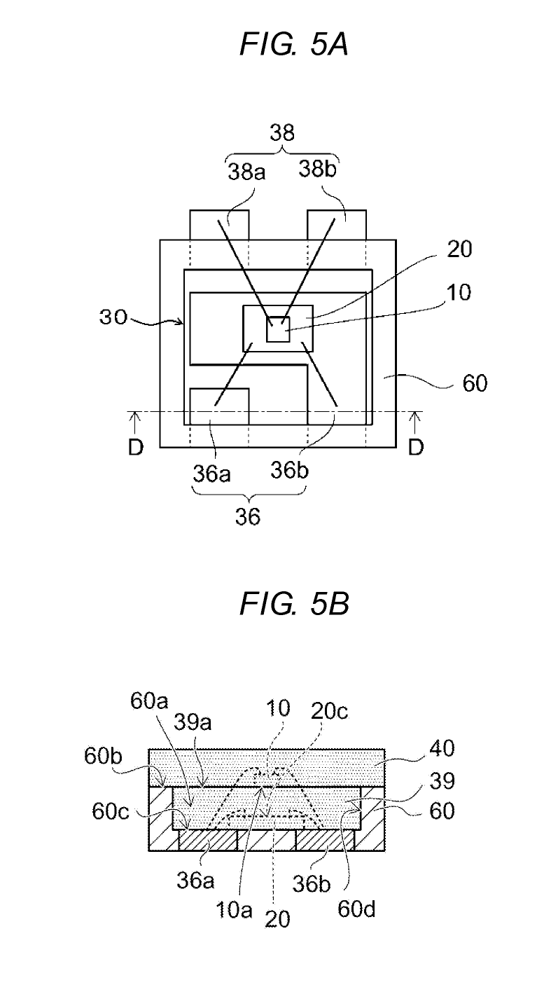

FIG. 5A is a plan view schematically illustrating an optical coupling device according to a second embodiment, and FIG. 5B is a side view schematically illustrating a cross section of the optical coupling device taken along a line D-D of FIG. 5A.

FIG. 5A is a plan view schematically illustrating a state before a second resin layer 40 is formed. The optical coupling device includes a mounting member 30, a light receiving element 20, a first resin layer 39, a light emitting element 10, and a second resin layer 40. The mounting member 30 includes an insulating layer 60 having a recess 60a and a light shielding property, input leads 38 buried in the insulating layer 60, and a first output lead 36a and a second output lead 36b buried in the insulating layer 60 so as to be insulated from the input leads 38. From a bottom 60c of the recess 60a, a portion of the first output lead 36a and a portion of the second output lead 36b are exposed.

The light receiving element 20 is adhered to the surface of the portion of the first output lead 36a, and uses its upper surface 20c as a light receiving surface. The light receiving element 20 is connected to the first output lead 36a and the second output lead 36b.

The first resin layer 39 is provided in the recess 60a so as to cover the light receiving element 20, and has a light transmitting property. The light emitting element 10 is adhered to the upper surface 39a of the first resin layer 39 such that its lower surface 10a acting as a light emitting surface faces the light receiving surface 20c, and is connected to the input leads 38. The second resin layer 40 is provided so as to cover the light emitting element 10, an upper surface 60b of the insulating layer 60 with the recess 60a, and the first resin layer 39.

The insulating layer 60 of the mounting member 30 may be insert molded. The recess 60a of the insulating layer 60 may have a shape obtained by cutting a rectangular shape, or a shape obtained by cutting a cone. The insulating layer 60 is suitable for mass production, and thus it may be possible to reduce the cost of production.

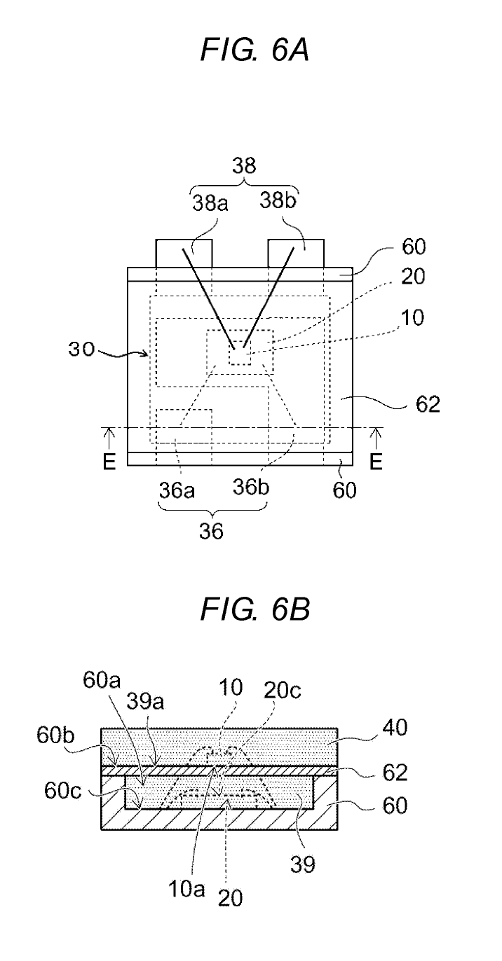

FIG. 6A is a plan view schematically illustrating an optical coupling device according to a third embodiment, and FIG. 6B is a schematic cross-sectional view taken along a line E-E of FIG. 6A.

FIG. 6A is a plan view schematically illustrating a state before a second resin layer 40 is formed. A mounting member 30 is the same as that of the second embodiment except that the mounting member includes a lead frame and an insulating layer 60 including an insert molding in which the lead frame is buried.

The third embodiment further includes a transparent plate 62 which is formed of glass or the like on the upper side of the mounting member 30. A light emitting element 10 is adhered on the transparent plate 62. In this case, bonding of wires to the light emitting element 10 may be easily performed. It is preferable that the transmittance of the transparent plate 62 should be 80% or more at 800 nm to 1,000 nm. On the transparent plate 62 with the light emitting element 10 adhered thereto, a molded body configured with the second resin layer 40 is formed.

According to the first to third embodiments, the lower surface of the light emitting element and the upper surface of the light receiving element face each other with a translucent resin interposed therebetween. Unlike in the comparative example, it is unnecessary to dispose lead frames in a vertical direction so as to face each other, and bend the lead frames. Therefore, the size of the optical coupling device may be reduced. The small-sized optical coupling device may be widely used for an air conditioner, a semiconductor tester, or the like requiring a number of optical coupling devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An optical coupling device comprising:
a mounting member that includes an insulating layer provided with a recess in an upper surface of the insulating layer, input terminals, and output terminals insulated from the input terminals;
a light receiving element provided on a bottom surface of the recess, is connected to the output terminals, and uses an upper surface of the light receiving element as a light receiving surface;
a first resin layer provided in the recess so as to cover the light receiving element;
a light emitting element adhered to an upper surface of the first resin layer such that a lower surface of the light emitting element has a light emitting surface facing the light receiving surface, and is connected to the input terminals; and
a second resin layer provided so as to cover the light emitting element, an upper surface of the insulating layer, the first resin layer, and the input terminals.

2. The optical coupling device of claim 1, wherein the mounting member and second resin layer have a light shielding property and wherein the first resin layer has a light transmitting property.

3. The optical coupling device of claim 1, wherein through-holes are formed through the insulating layer and wherein the output terminals connect conductive regions provided at two surfaces of the insulating layer via conductive regions provided within the through-holes.

4. The optical coupling device according to claim 1, wherein
the input terminals are provided on an upper surface of the insulating layer.

5. The optical coupling device of claim 1, wherein:
the input terminals are provided on a first side surface of the insulating layer, and
the output terminals are provided on a second side surface side of the insulating layer opposite to the first side surface.

6. The optical coupling device of claim 1, wherein the insulating layer contains a ceramic or a resin.

7. The optical coupling device according to claim 1, wherein the first and second resin layer are formed of a thermoset resin.

8. The optical coupling device according to claim 1, wherein the light emitting element is adhered to a planarized portion of the first rein layer.

9. The optical coupling device of claim 1, wherein the input terminals and output terminals do not protrude laterally from the mounting member.

10. An optical coupling device comprising:
a mounting member including an insulating layer provided with a recess in an upper surface of the insulating layer, input leads buried in the insulating layer, and first and second output leads buried in the insulating layer;
a light receiving element adhered to a surface of the portion of the first output lead and connected to the first output lead and the second output lead, wherein an upper surface of the light receiving element is a light receiving surface;
a first resin layer provided in the recess and covering the light receiving element;
a light emitting element adhered to an upper surface of the first resin layer such that a lower surface of the light emitting element providing a light emitting surface faces the light receiving surface, and is connected to the input terminals; and
a second resin layer covering the light emitting element, an upper surface of the recess of the insulating layer, and the first resin layer.

11. The optical coupling device of claim 10, wherein the first and second output leads are insulated from the input leads.

12. The optical coupling device of claim 11, wherein a portion of the first output lead and a portion of the second output lead are exposed at a bottom surface of the recess.

13. The optical coupling device of claim 10, wherein the mounting member and second resin layer have a light shielding property and wherein the first resin layer has a light transmitting property.

14. The optical coupling device of claim 10, wherein the insulating layer is an insert molding.

15. The optical coupling device of claim 10, wherein the recess is of a rectangular shape.

16. An optical coupling device comprising:
a mounting member that includes an insulating layer provided with a recess hollowed from an upper surface of the insulating layer, input leads buried in the insulating layer, and first and second output leads buried in the insulating layer and a portion of the first output lead and a portion of the second output lead are exposed from a bottom of the recess;
a light receiving element that is adhered to a surface portion of the first output lead, and uses an upper surface of the light receiving element as a light receiving surface, and is connected to the first output lead and the second output lead;
a first resin layer that is provided in the recess so as to cover the light receiving element;
a transparent plate that is provided on an upper surface of the recess of the insulating layer so as to cover the first resin layer;
a light emitting element that is adhered to an upper surface of the transparent plate such that a lower surface of the light emitting element includes a light emitting surface facing the light receiving surface, and is connected to the input terminals; and
a second resin layer that is provided so as to cover the light emitting element and the transparent plate.

17. The optical coupling device of claim 16, wherein the first and second output leads are insulated from the input leads.

18. The optical coupling device of claim 16, wherein a portion of the first output lead and a portion of the second output lead are exposed at a bottom surface of the recess.

19. The optical coupling device of claim 16, wherein the mounting member and second resin layer have a light shielding property and wherein the first resin layer has a light transmitting property.

20. The optical coupling device of claim 16, wherein a transmittance of the transparent plate is 80% or greater at wavelengths at and between 800 nm to 1,000 nm.
